(19) United States
(12) Patent Application Publication
(10) Pub. No.: US 2007/0040222 A1
(43) Pub. Date: Feb. 22, 2007

(54) Method and apparatus for improved ESD performance

(76) Inventors: Benjamin Van Camp, Antwerpen (BE); Gerd Vermont, Ruiselede (BE); Bart Keppens, Gistel (BE)

Correspondence Address: PATENT DOCKET ADMINISTRATOR;LOWENSTEIN SANDLER P.C., 65 LIVINGSTON AVENUE, ROSELAND, NJ, 07068, US

(21) Appl. No.: 11/451,188

(22) Filed: Jun. 12, 2006

Related U.S. Application Data
(60) Provisional application No. 60/690,933, filed on Jun. 15, 2005.

(51) Int. Cl. H01L 23/62

(52) U.S. Cl. 257/357

(57) ABSTRACT

The present invention provides an integrated circuit for improved ESD protection and method of forming the same. The integrated circuit comprises a substrate and an insulating layer formed over the substrate. The circuit also comprises a field effect field effect transistor (FET) formed over the insulating layer. The FET includes a well region of a first conductivity type. The circuit also includes a well resistor coupled to the FET to provide ballasting to the circuit. The well resistor includes a well region also of the first conductivity type.

### CROSS REFERENCES

This patent application claims the benefit of U.S. Provisional Application Ser. No. 60/690,933 filed Jun. 15, 2006, the contents of which are incorporated by reference herein.

### FIELD OF THE INVENTION

This invention generally relates to the field of electrostatic discharge (ESD) protection circuitry, and more specifically, for providing ballasting circuitry to improve ESD performance of metal oxide semiconductor (MOS) devices in the circuitry of an integrated circuit (IC) in silicon on insulator (SOI).

### BACKGROUND OF THE INVENTION

Integrated circuits (IC's) including field effect transistors (FET) and other semiconductor devices are extremely sensitive to the high voltages that may be generated by contact with an ESD event. As such, electrostatic discharge (ESD) protection circuitry is essential for integrated circuits. An ESD event commonly results from the discharge of (a high voltage potential (typically, several kilovolts) and leads to pulses of high current (several amperes) of a short duration (typically, 100 nanoseconds). An ESD event is generated within an IC, illustratively, by human contact with the leads of the IC or by electrically charged machinery being discharged in other leads of an IC. During installation of integrated circuits into products, these electrostatic discharges may destroy the IC's and thus require expensive repairs on the products, which could have been avoided by providing a mechanism for dissipation of the electrostatic discharge to which the IC may have been subjected.

It is well known that for improving the ESD performance of NMOS devices ballasting is very crucial. Ballasting means the adding of resistance to the drain of the NMOS to avoid current crowding (micro-ballasting) and to improve multifinger triggering (macro-ballasting). The most common way to create ballasting is by increasing the drain contact to gate spacing (DCGS) and adding a silicide block region to increase the resistance of the drain. This is illustrated in FIG. 1 with the equivalent schematic circuit for a 2 finger NMOS is shown in FIG. 2.

Applying silicide block to the drain region of an ESD protection device, is very costly, because an extra mask is needed during the processing. It's also possible to leave the silicide block out but then the DCGS must be very large and area inefficient. The reason for this is the low resistance of the silicide. The needed resistance would be large.

### SUMMARY OF THE INVENTION

In one embodiment of the present invention, there is provided an integrated circuit having a substrate and an circuit node comprising an insulating layer formed over the substrate, and a field effect transistor (FET) formed over the insulating layer. The FET includes a highly doped source and drain regions of a first conductivity type formed at spaced apart locations over the insulating layer, and a well region of a second conductivity type formed over the insulating layer between the spaced apart source and drain regions. The circuit also comprises a first well region of the second conductivity type formed over the insulating layer at the drain region of the FET, and having a resistance for the current flowing from the circuit node to the FET. The first well region is electrically coupled to the circuit node.

In another embodiment of the present invention, there is provided an integrated circuit having a substrate and an circuit node comprising an insulating layer formed over the substrate and a field effect transistor (FET) formed over the insulating layer. The FET includes a highly doped source and drain regions of a first conductivity type formed at spaced apart locations over the insulating layer, and a well region of a second conductivity type formed over the insulating layer between the spaced apart source and drain regions. The circuit also comprises a first well region of the first conductivity type formed over the insulating layer at the drain region of the FET, and having a resistance for the current flowing from the circuit node to the FET. The first well region is electrically coupled to the circuit node.

In a further embodiment of the present invention, there is provided a method of improving an ESD robustness of a FET comprising placing the FET on a substrate and coupling a well resistor to the FET to provide resistance of the well resistor to ballast the FET.

### BRIEF DESCRIPTION OF THE DRAWINGS

FIG. 1 depicts an illustrative cross-section diagram of a prior art illustrating a usage of silicide block as a ballasting device.

FIG. 2 depicts a schematic diagram of a prior art illustrating a two-finger NMOS with drain ballasting.

FIG. 3A depicts an illustrative cross-section diagram of one finger protection device with Pwell ballasting for an NMOS device according to one embodiment of the present invention.

FIG. 3B depicts an illustrative cross-section diagram of multiple finger protection device with Pwell ballasting for an NMOS device according to another embodiment of the present invention.

FIG. 3C depicts an illustrative cross-section diagram of multiple finger protection device with Pwell ballasting for an NMOS device according to an alternate embodiment of the present invention.

FIG. 3D depicts an illustrative cross-section diagram of the protection device of FIG. 3A according to another embodiment of the present invention.

FIG. 3E depicts an illustrative cross-section diagram of the protection device of FIG. 3A according to further embodiment of the present invention.

FIG. 3F depicts an illustrative cross-section diagram of the protection device of FIG. 3A according to even further embodiment of the present invention.

FIG. 4 depicts an illustrative cross-section diagram of Nwell ballasting for a PMOS device according to an alternative embodiment of the present invention.

FIG. 5 depicts an illustrative cross-section diagram of Nwell ballasting for a NMOS device according to another alternative embodiment of the present invention.

FIG. 6 depicts an illustrative cross-section diagram of Pwell ballasting for a PMOS device according to another alternative embodiment of the present invention.

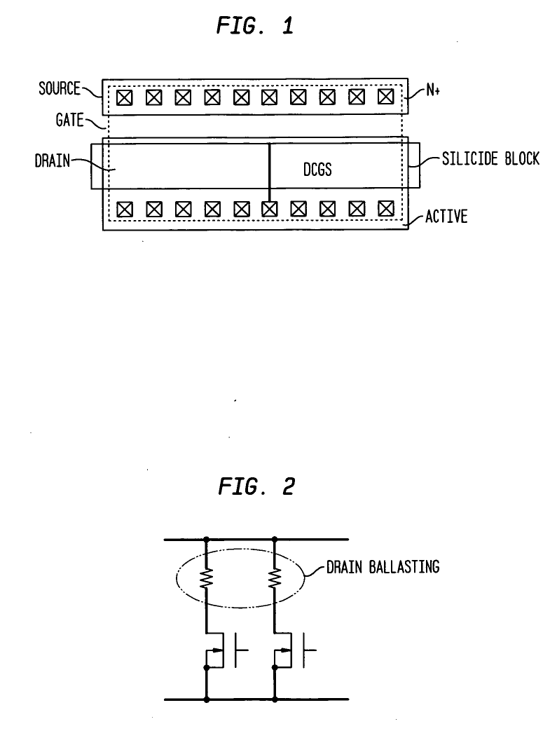

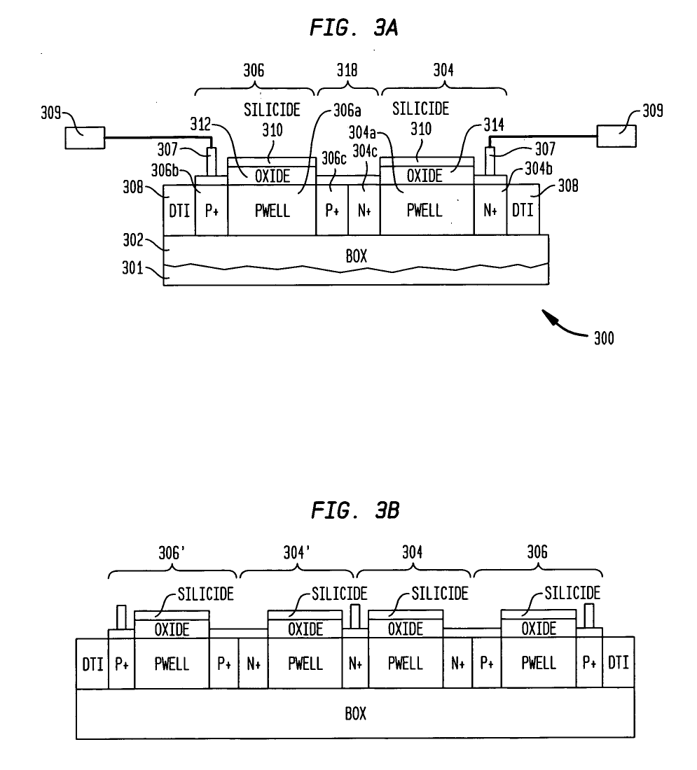

### DETAILED DESCRIPTION OF THE INVENTION

The process steps and structures described below do not form a complete process flow for manufacturing integrated circuits (ICs). The present invention can be practiced in conjunction with silicon-on-insulator (SOI) integrated circuit fabrication techniques currently used in the art, and only so much of the commonly practiced process steps are included as are necessary for an understanding of the present invention. The figures representing cross-sections and layouts of portions of an IC during fabrication are not drawn to scale and to form, but instead are drawn so as to illustrate the important features of the invention.

The present invention is described with reference to SOI CMOS devices. However, those of ordinary skill in the art will appreciate that for instance selecting different dopant types, adjusting concentrations or changing the isolation types allows the invention to be applied to other processes that are susceptible to damage caused by ESD.

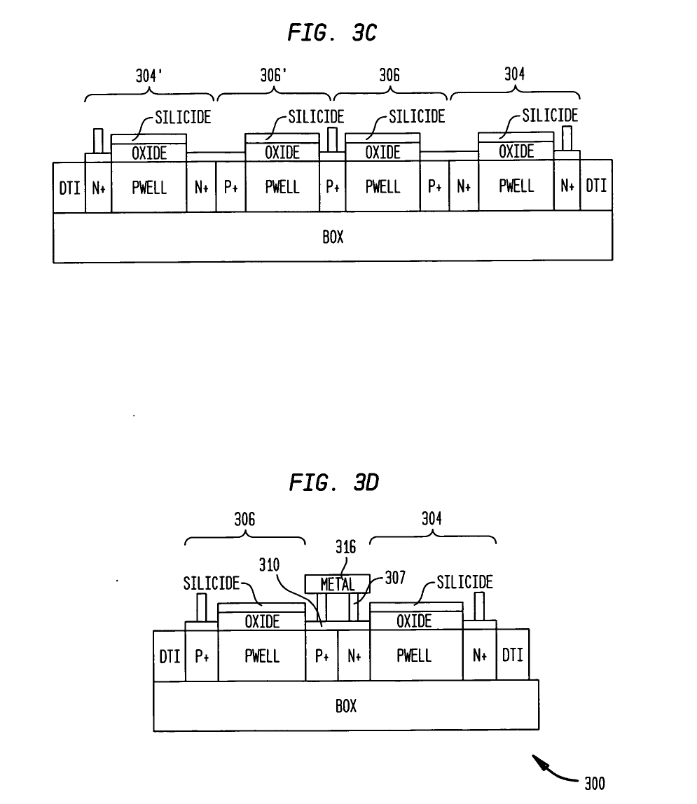

Referring to FIG. 3A, a cross-section diagram of an integrated circuit device 300 comprising a P-well ballasting for the NMOS transistor is shown, according to one embodiment of the present invention. The device 300 includes a substrate 301 such as a P-type substrate, and a buried insulating layer 302 (e.g. SiO2, hereinafter buried oxide (BOX) layer) disposed over the substrate. An NMOS transistor 304 and a P well resistor 306 are formed over the buried oxide layer 302. Preferably, two deep trench isolations (DTIs) regions 308, are formed at each end of the substrate 301. In particular, the DTI regions 308 extend down to the buried oxide layer 302. It is noted that even though DTI is used as an one example of the isolation, it's also possible to use partial trench isolation (PTI) shallow trench isolation (STI), or other isolations known in the art. Alternatively, it is even possible to not include these isolations and place another device adjacent to this structure. As shown in FIG. 3A, the NMOS transistor 304 includes a highly doped source region 304b and a highly doped drain region 304c of a N conductivity type formed at spaced apart locations over the insulating layer 302 as shown in FIG. 3A. The NMOS transistor 304 also includes a P-well region 304a of a P conductivity type formed over the insulating layer 302 at the gate channel, between the spaced apart source 304b and drain region 304c.

Additionally, as illustrated in FIG. 3A, the P-well resistor 306 includes a P-well region 306a of P conductivity type formed over the insulating layer 302 at the drain region 304c of the NMOS transistor 304. Also, shown in FIG. 3A are contacts 307 formed over the source region 304b of the NMOS transistor 304 and over the P-well region 306a of the P-well resistor. The contacts 307 lead to a circuit node 309. The P-well region 306a has a resistance for the current flowing via the contacts 307 between the circuit node 309 and the NMOS 304. The P-well resistor 306 also includes a P+ region 306b formed over the insulating layer 302 in the P-well region 306a as shown. The P-well resistor 306 can further include another P+ region 306c formed over the insulating layer 302 in the P-well region 306a adjacent to the N+ drain region 304c of the NMOS 304. The P+ region 306c and the N+ drain region 304c form a PN junction 318 between the P-well 304a and the P-well 306a as shown in FIG. 3A.

It is noted that the buried insulating layer 302 is illustratively fabricated from silicon dioxide (SiO.sub.2), sapphire (SOS), among other insulating materials. In one embodiment, the BOX layer 302 is formed by implanting and annealing oxygen atoms in a wafer to form the silicon dioxide layer therein. The thickness (t.sub.BOX) of the BOX layer 302 is typically in a range of approximately 100 to 400 nanometers (nm).

As illustrated in FIG. 3A, a silicide layer 310 is formed over each of the N+ source region 304b and the drain region 304c of the NMOS 304. The silicide layer 310 is also formed over each of the P+ regions 306b and 306c of the P-well resistor 306. Thus, the silicide layer 310 is formed over the PN junction 318 (i.e. the P+ drain region 306c and the N+ drain region 304c ). The silicide layer 310 is provided to shorten the two highly doped regions. The silicide layers 310 are formed in a conventional manner known in the art and serve as a conductive material for a metal connection. The silicide layer 310 is a very thin metal to make a low ohmic connection. This layer provides a better contact to the highly doped region.

Furthermore, as shown in FIG. 3A, a gate G1 312 is formed in the Pwell region 306a of the Pwell resistor 306, and a gate G2 314 is formed in the P-well region 304a of the NMOS 304. A classical way to make these gates is to use poly silicium on an oxide, however it's also possible to use other techniques and materials like FUSI or other materials known in the art. Preferably, the gate G1 in the resistor is made to use the Pwell 304 as an resistance. This is because the lowly doped well has a larger resistance than the highly doped regions. The advantage to this preferred use is that due to the larger resistance of the well, the resistor can be smaller for a given value of needed resistance. The placement of the gate prevents the DTI to be formed in the well under the gate.

It is important to note the protection device 300 shown in FIG. 3A is a single finger device with the NMOS transistor 304 and the P-well ballasting 306 formed between the two deep trench isolations (DTIs) 308. However, the device 300 may have multiple fingers as shown in FIG. 3B with P-well ballasting 306 and 306′ respectively. In this embodiment, the source of one finger of the FET, i.e. the NMOS 304 is shared with the source of the other finger of NMOS 304′ as shown in FIG. 3B. Although, not shown, its known to the one skilled in the art that the two sources can also be adjacent to each other, but this implies a larger area. Furthermore, the two DTIs 308 are formed at each end of the substrate 301. As discussed above, it is possible to leave the DTI out and replace it with another device. Alternatively, the device 300 may have multiple fingers as shown in FIG. 3C in which one region of the Pwell resistor 306 can be shared by the one region of the Pwell resistor 306′.

Furthermore, in another embodiment of the invention, at least one metal line 316 is used to provide a parallel current path to the silicide layer 310 as shown in FIG. 3D. The region 306C is coupled to 304C through the silicide 310 and also through the contact 307 and metal line 316. In this embodiment both the metal lines 316 and the silicide layer 310 short-circuit the two highly doped regions. The metal lines 316 are used to connect the resistor to the drain of MOS. Specifically, in the example of FIG. 3D, the metal lines 316 connect the P-well resistor 306 to the drain region 304c of the NMOS 304. Since, the metal lines 316 are much stronger than silicide, it provides a better connection.

In a further embodiment of the present invention, the PN junction 308 between the P-well 304a and the P-well 306a is preferably represented by a diode 318 as shown in FIG. 3E. Specifically, the silicide layer 310 is left out over the PN junction (use of a silicide block layer) to create the diode 318 between the P+ region 306c and the N+ region 304c, to increase the ballasting effect. Now the voltage is not only built over a resistor but also over the diode 318. This implies an extra voltage, i.e. the built-in voltage of the diode. Thus, in this structure, ballasting can preferably be achieved not by using only the resistor, but, also by including the diode 318. Note that the diode is already available in the structures shown in FIGS. 3A-3D i.e. the P+ region of the resistor 306 adjacent to the drain 304c of the NMOS 304, and it was short circuited, therefore, the diode 318 was inactive. However, in FIG. 3E, there is no short-circuiting the diode 318, therefore, the diode 318 is active. Additionally, the diode 318 is formed very easily without using extra space in the device structure 300.

In an even further embodiment of the present invention, a further improvement in the ballasting effect is shown by omitting the central P+ region 306c of the P-well ballasting 306 as illustrated in FIG. 3F. By adding a resistance, the current will flow more uniformly and this helps the MOS to trigger. Higher resistance improves this effect. But the P+ region in the previous figures eliminate a part of this advantage by providing a lower ohmic connection to the drain of MOS 304, than the Pwell 306. Eliminating the P+ region 306, preferably provides at least three advantages. First, the area of the structure device 300 can be made much smaller. Second, the current will flow directly from the well 306 to the drain 304c of the NMOS 304. The third advantage is that a PN-junction is still created in the structure. The PN-junction is formed between the Pwell 306a and the drain 304c of the FET.

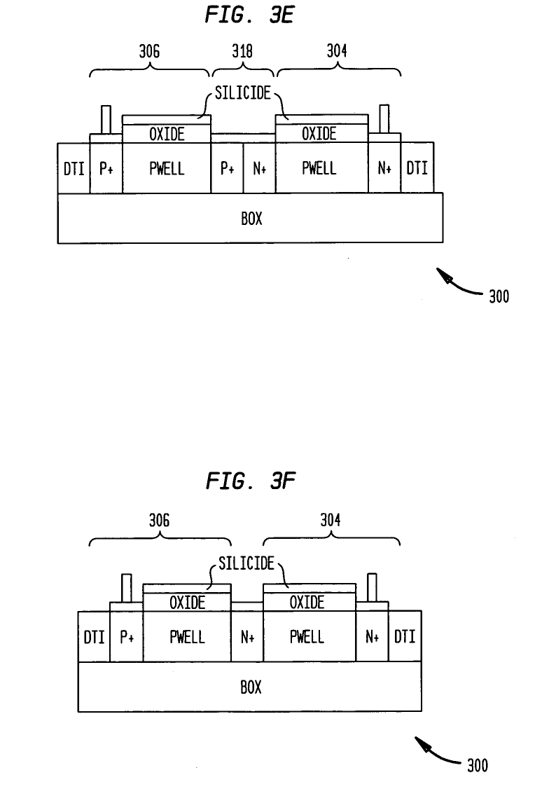

Referring to FIG. 4, an alternate embodiment of the present invention with an integrated circuit device 400 comprising a N-well ballasting for the PMOS transistor is shown. Similar to FIG. 3A, the device 400 comprises a substrate 301 with a buried insulating layer 302 disposed over the substrate 301, and two DTI regions 308 are formed at each end of the substrate 301. As shown in FIG. 4, a PMOS transistor 404 includes highly doped source region 404b and a highly doped drain region 404c of a P conductivity type formed at spaced apart locations over the insulating layer 302 as shown in FIG. 4. The PMOS transistor 404 also includes a N-well region 404a of a N conductivity type formed over the insulating layer 302 at the gate channel, between the spaced apart source 404b and drain region 404c.

Additionally, as illustrated in FIG. 4, a N-well resistor 406 includes a N-well region 406a of N conductivity type formed over the insulating layer 302 at the drain region 404c of the PMOS transistor 404. The N-well region 406a has a resistance for the current flowing via the contacts 307 between the circuit node and the PMOS 404. The N-well resistor 406 also includes a N+ region 406b formed over the insulating layer 302 in the N-well region 406a as shown. The N-well resistor 406 further includes another N+ region 406c formed over the insulating layer 302 in the N-well region 406a adjacent to the P+ drain region 404c of the PMOS 404. The P+ region 406c and the N+ drain region 404c form a PN junction 310 between the N-well 404a and the N-well 406a as shown in FIG. 4.

The silicide layer 310 as discussed above is formed over each of the P+ source region 404b and the drain region 404c of the PMOS 404. The silicide layer 310 is also formed over each of the N+ regions 406b and 406c of the N-well resistor 406. Thus, the silicide layer 310 is formed over the PN junction 310 (i.e. the P+ drain region 406c and the N+ drain region 404c ). The silicide layer 310 is applied to short-circuit between the high doped regions. The silicide layers 310 are formed in a conventional manner known in the art and serve as a conductive material to allow a good connection. The silicide layer 310 is a very thin metal to make a low ohmic connection. This layer provides a better contact to the highly doped region.

Furthermore, as shown in FIG. 4, a gate G1 412 is formed in the Nwell region 406a of the Nwell resistor 406, and a gate G2 414 is formed in the N-well region 404a of the PMOS 404. As discussed above, the classical way to make these gates is to use poly with a gate oxide, however, it's also possible to use FUSI, or other materials known in the art. The placement of the gate prevents the DTI to be formed in the well under the gate. Preferably, the gate G1 in the resistor is made to use the Nwell 406 as an resistance. This is because the lowly doped well has a larger resistance than the highly doped regions. The advantage to this preferred use is that due to the larger resistance of the well, the resistor can be smaller for a given value of needed resistance.

The specific properties of the SOI circuit as disclosed above allow for the usage of a Pwell as ballasting for an NMOS drain and of a N-well as ballasting for a PMOS drain as disclosed in detail above. One of the key advantages of the invention is the usage of a well of the same doping type as is used in the CMOS. Difference in threshold implant between the wells is, however, possible. An additional benefit of this implementation as compared to some other ballasting techniques is that the contact to the circuit node is spaced far away from the drain junction, such that the hotspot of the drain junction and the hotspot of the contact don't influence each other

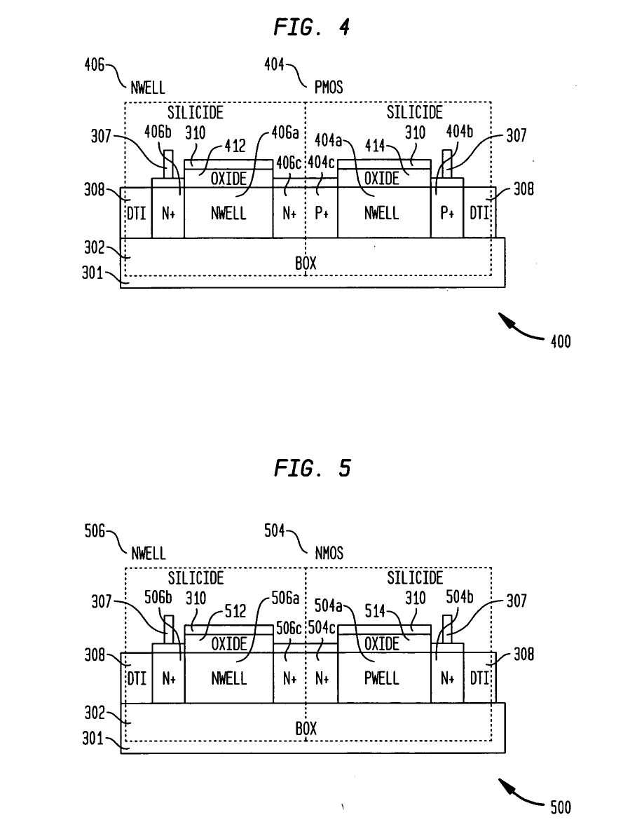

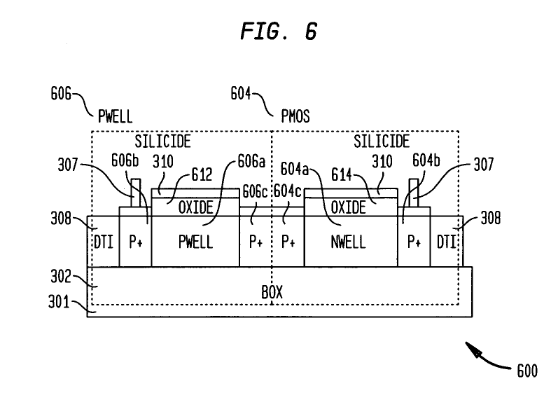

In an further embodiment of the present invention, there is shown an integrated circuit device 500 in FIG. 5 and device 600 in FIG. 6 of a well resistor having a different doping type as is used in the CMOS.

Specifically, with reference to FIG. 5, the device 500 comprises N-well ballasting for the NMOS transistor. Similar to FIG. 3A, the device 500 comprises a substrate 301 with a buried insulating layer 302 disposed over the substrate 301, and two DTI regions 308 are formed at each end of the substrate 301. As shown in FIG. 5, an NMOS transistor 504 includes highly doped source region 504b and a highly doped drain region 504c of a N conductivity type formed at spaced apart locations over the insulating layer 302 as shown in FIG. 5. The NMOS transistor 504 also includes a P-well region 504a of a P conductivity type formed over the insulating layer 302 at the gate channel, between the spaced apart source 504b and drain region 504c.

Additionally, as illustrated in FIG. 5, an N-well resistor 506 includes a N-well region 506a of N conductivity type formed over the insulating layer 302 at the drain region 504c of the NMOS transistor 504. The N-well region 506a has a resistance for the current flowing via the contacts 307 between the circuit node and the NMOS 504. The N-well resistor 506 also includes a N+ region 506b formed over the insulating layer 302 in the N-well region 506a as shown. The N-well resistor 506 further includes another N+ region 506c formed over the insulating layer 302 in the N-well region 506a adjacent to the N+ drain region 504c of the NMOS 504.

The silicide layer 310 as discussed above is formed over each of the N+ source region 504b and the drain region 504c of the NMOS 504. The silicide layer 310 is also formed over each of the N+ regions 506b and 506c of the N-well resistor 506. The silicide layer 310 is provided to short-circuit between the high doped regions. The silicide layers 310 are formed in a conventional manner known in the art and serve as a conductive material for a metal contact. The silicide layer 310 is a very thin metal to make a low ohmic connection. This layer provides a better contact to the highly doped region.

Furthermore, as shown in FIG. 5, a gate G1 512 is formed in the Nwell region 506a of the Nwell resistor 506, and a gate G2 514 is formed in the P-well region 504a of the NMOS 504. As discussed above, a classical way to make the gates G1 412 and G2 414 is to use poly silicium and gate oxide, however it is also possible to use FUSI or other materials known in the art. Also, G1 512 in the resistor is made to use the Nwell 506 as an resistance due to the fact that the lowly doped well has a larger resistance than the highly doped regions. The placement of the gate prevents the DTI to be formed in the well under the gate.

Specifically, with reference to FIG. 6, the device 600 comprises P-well ballasting for the PMOS transistor. Similar to FIG. 3A, the device 600 comprises a substrate 301 with a buried insulating layer 302 disposed over the substrate 301, and two DTI regions 308 are formed at each end of the substrate 301. As shown in FIG. 6, an PMOS transistor 604 includes highly doped source region 604b and a highly doped drain region 604c of a P conductivity type formed at spaced apart locations over the insulating layer 302 as shown in FIG. 6. The PMOS transistor 604 also includes a N-well region 604a of a N conductivity type formed over the insulating layer 302 at the gate channel, between the spaced apart source 604b and drain region 604c.

Additionally, as illustrated in FIG. 6, an P-well resistor 606 includes a P-well region 606a of P+ conductivity type formed over the insulating layer 302 at the drain region 604c of the NMOS transistor 604. The P-well region 606a has a resistance for the current flowing via the contacts 507 between the circuit node and the PMOS 604. The P-well resistor 606 also includes a P+ region 606b formed over the insulating layer 302 in the P-well region 606a as shown. The P-well resistor 606 further includes another P+ region 606c formed over the insulating layer 302 in the P-well region 606a adjacent to the P+ drain region 604c of the PMOS 604.

The silicide layer 310 as discussed above is formed over each of the P+ source region 604b and the drain region 604c of the PMOS 604. The silicide layer 310 is also formed over each of the P+ regions 606b and 606c of the P-well resistor 606. The silicide layer 310 is provided to prevent shorting between the high doped regions. The silicide layers 310 are formed in a conventional manner known in the art and serve as a conductive material for a metal contact. The silicide layer 310 is a very thin metal to make a low ohmic connection. This layer provides a better contact to the highly doped region.

Furthermore, as shown in FIG. 6, a gate G1 612 is formed in the P-well region 606a of the Nwell resistor 606, and a gate G2 614 is formed in the N-well region 604a of the NMOS 604. As discussed above, each of the gates G1 612 and G2 614 are made by using poly silicium and gate oxide, however, it is also possible to use FUSI, or other materials known in the art. The placement of the gate prevent the DTI to be formed in the well under the gate. Preferably, the gate G1 in the resistor is made to use the Nwell resistor 606 as resistance. This is because the lowly doped well has a larger resistance than the highly doped regions.

Although various embodiments that incorporate the teachings of the present invention have been shown and described in detail herein, those skilled in the art can readily devise many other varied embodiments that still incorporate these teachings without departing from the spirit and the scope of the invention.

1. An integrated circuit having a substrate and an circuit node comprising:
an insulating layer formed over said substrate;
a field effect transistor (FET) formed over said insulating layer, said FET having a highly doped source and drain regions of a first conductivity type formed at spaced apart locations over said insulating layer, and a well region of a second conductivity type formed over said insulating layer between said spaced apart source and drain regions;
a first well region of said second conductivity type formed over said insulating layer at said drain region of said FET, and having a resistance for the current flowing between said circuit node and said FET;

2. The circuit of claim 1 further comprising a first highly doped region of the second conductivity type formed in said first well region

3. The circuit of claim 2 further comprising a second highly doped region of the second conductivity type formed over said insulating layer in the first well region adjacent to the highly doped drain region of the first conductivity type of said FET, said second highly doped region of the second conductivity type and said highly doped drain region of the first conductivity type forming a PN junction.

4. The circuit of claim 1 wherein a first gate is formed between the source and drain of said FET and over the well region of said FET

5. The circuit of claim 4 wherein a second gate is formed over at least a part of the said first well region

6. The circuit of claim 4 wherein said first gate and said second gates are polygates.

7. The circuit of claim 3 wherein said second highly doped region of second conductivity type is coupled to the drain of said FET through at least one of silicide or metal.

8. The circuit of claim 3 wherein said second highly doped region of second conductivity type and the drain of said FET form a diode between the first well and the drain of said FET.

9. The circuit of claim 1 wherein said first conductivity type comprises one of n or p conductivity type.

10. The circuit of claim transistor of claim 9 wherein said second conductivity type comprises other of the n or p conductivity type.

11. An integrated circuit having a substrate and an circuit node comprising:
an insulating layer formed over said substrate;
a field effect transistor (FET) formed over said insulating layer, said FET having a highly doped source and drain regions of a first conductivity type formed at spaced apart locations over said insulating layer, and a well region of a second conductivity type formed over said insulating layer between said spaced apart source and drain regions;
a first well region of said first conductivity type formed over said insulating layer at said drain region of said FET, and having a resistance for the current flowing between said circuit node and said FET;

12. The circuit of claim 11 further comprising a first highly doped region of the first conductivity type formed in said first well region

13. The circuit of claim 12 further comprising a second highly doped region of the first conductivity type formed over said insulating layer in the first well region adjacent to the highly doped drain region of the first conductivity type of said FET.

14. The circuit of claim 11 wherein a first gate is formed between the source and drain of said FET and over the well region of said FET

15. The circuit of claim 11 wherein a second gate is formed over at least a part of the said first well region

16. The ESD circuit of claim 13 wherein said second highly doped region of first conductivity type is coupled to the drain of said FET through at least one of silicide or metal.

17. An integrated circuit having a substrate and an circuit node comprising:
an insulating layer formed over said substrate;
at least one field effect field effect transistor (FET) formed over said insulating layer, wherein said FET having a well region of first conductivity type; and
a well resistor coupled to the FET to provide ballasting to the circuit, wherein said resistor having a well region of the first conductivity type.

18. The circuit of claim 17 further comprising a layer of silicide is formed to couple the well resistor to the FET.

19. A method of improving an ESD robustness of a FET comprising:
placing said FET on a substrate; and
coupling a well resistor to the FET to provide resistance of the well resistor to ballast the FET

20. The method of claim 19 wherein said coupling further comprising forming a layer of silicide between the FET and the well resistor.
